(19) United States
(12) Patent Application Publication
(10) Pub. No.: US 2003/0074610 A1
(43) Pub. Date: Apr. 17, 2003

(54) Method for improving utilization of a defective memory device in an image processing system

(75) Inventors: Shih-Huang Chen, Hsin-Chu (TW); Yin-Chun Huang, Hsin-Chu (TW)

Correspondence Address: LOWE HAUPTMAN GILMAN, & BERNER, LLP, Suite 310, 1700 Diagonal Road, Alexandria, VA, 22314, US

(73) Assignee: UMAX DATA SYSTEMS INC.

(21) Appl. No.: 09/977,309

(22) Filed: Oct. 16, 2001

(51) Int. Cl. H04L 1/22; H04B 1/74; H02H 3/05; H05K 10/00; H03K 19/003; G11C 29/00

(52) U.S. Cl. 714/710

(57) ABSTRACT

A utilization of a defective memory device in an image processing system is provided. The present invention provides three methods for utilizing the defective memory device to serve as an image data storage device. A first method is selecting at least a block of functional memory cells to store image data. A second method is using functional memory cells to store image data while skipping through defective memory cells in accordance with a mapping table of the defective memory cells and their positions in the memory array. A third method is using the defective memory device to store image data and then re-estimating image value of a pixel corresponding to each defective memory cell by an interpolation technique.

### BACKGROUND OF THE INVENTION

1. Field of the Invention

The present invention relates to utilization of a defective memory device, and more particularly to utilization of a defective memory device in an image processing system.

2. Description of the Prior Art

Please refer to FIG. 1. FIG. 1 is a schematically cross-sectional view of a prior image processing system, such as a scanner 10. The scanner 10 comprises a body 11 with a transparent platform 12 on its top end for placing a document to be scanned, and a scanner head 13 is positioned under the transparent platform 12 to scan the document placed on the transparent platform 12. The scanner head 13 slides on a belt 14 by way of a transmission means (not shown). The scanner head 13 usually comprises a housing 15 with a light source 16, an optical system including a set of mirrors 17 and a lens 18, a photosensitive detector 19, and a driving device 20 installed therein. The photosensitive detector 19, such as a CCD (charge coupled device), detects the image light focused thereon by the optical system reflected from the document. Referring to FIG. 3, the driving device 20 including three transistors provides driving capability to drive a processing unit installed in a main board 22. Referring to FIG. 2, the processing unit comprises an analog-to-digital converter (ADC) 23, a control circuit 24, such as an application specific integrated circuit (ASIC), a memory 25, an interface control circuit 26 and a motor control circuit 27. Referring to FIG. 3, the analog signal of the photosensitive detector 19 and the driving signal of the driving device 20 are transmitted to the processing unit through a cable 21. The analog-to-digital converter 23 digitizes the analog signal received from the photosensitive detector 19 and outputs the digitized signal to the control circuit 24. The information of the control circuit 24 is stored in the memory 25. And, the information of the control circuit 24 is outputted to a host through an interface 28 controlled by an interface control circuit 26.

During fabrication of memory devices, one or more defects may occur and prevent the proper performance of the memory circuit. Therefore, a defective memory device is generally not used as an image information storage device in the image processing system. The defective memory devices arising during the memory fabrication are useless and the functional memory cells therein are wasted. The production cost of the memory device still has a higher price than other electronic devices used in the image processing system, such as the scanner. Since the defective memory devices are useless, the scanner cost could not be reduced.

Accordingly, there is a need to develop a method for utilizing a defective memory device in an image processing system, such as a scanner, to overcome the drawback of low utilization of the defective memory device and its waste of some functional memory cells.

### SUMMARY OF THE INVENTION

It is one objective of the present invention to provide a method for improving utilization of a defective memory device in an image processing system, which can efficiently and economically utilize the defective memory, and thus obtain the purpose of cost down.

It is a further objective of the present invention to provide a method for improving utilization of a defective memory device in an image processing system, which can increase storage capacity of the memory device used in the image processing system.

In order to achieve the above objectives of this invention, the present invention provides three methods for utilizing a defective memory device in an image processing system. When power is initially applied to the image processing system, the detection of defective memory cells is executed by writing a predetermined test data pattern to the memory cell array. Storing positions of the defective memory cells in the memory cell array. Selecting at least a block of functional memory cells to store image data obtained by an image reading device of the image processing system. Alternately, establishing a mapping table of the defective memory cells and their positions in the memory cell array, and using functional memory cells to store the image data while skipping through the defective memory cells in accordance with the mapping table. Another alternative method is using the defective memory device to store the image data and re-estimating an image value of a pixel corresponding to each defective memory cell by an interpolation technique.

### BRIEF DESCRIPTION OF THE DRAWINGS

The objectives and features of the present invention as well as advantages thereof will become apparent from the following detailed description, read in conjunction with the accompanying drawings, wherein:

FIG. 1 is a schematically cross-sectional view of a prior scanner;

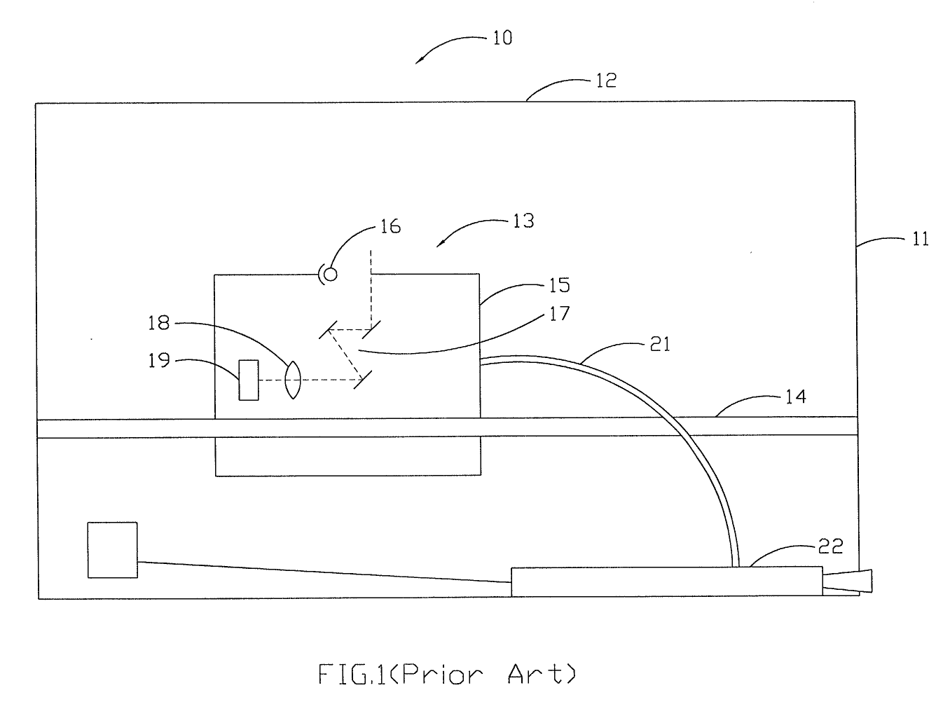

FIG. 2 is a function block diagram of a processing unit of the prior scanner of FIG. 1;

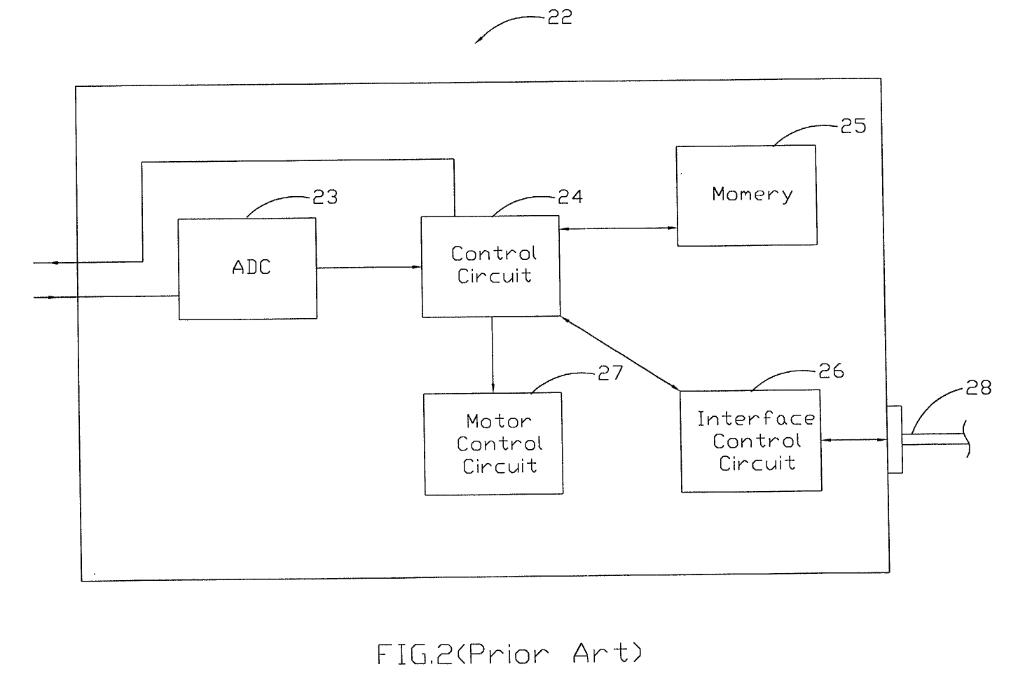

FIG. 3 is a schematic view for showing signal transmission between a scanner head and the processing unit of the prior scanner of FIG. 1;

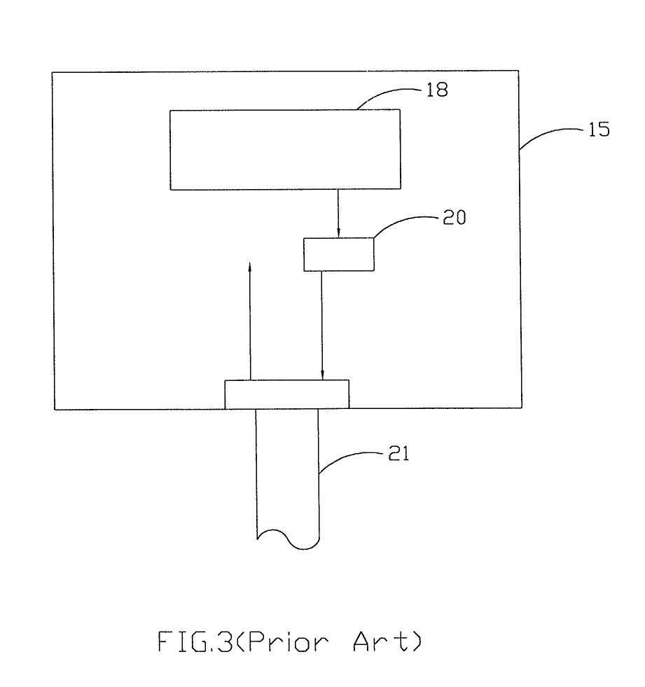

FIG. 4 is a schematic circuit showing the detection of defective memory cells is executed by the control circuit;

FIG. 5 is a flow chart according to a first embodiment of the present invention;

FIG. 6 is a flow chart according to a second embodiment of the present invention; and

FIG. 7 is a flow chart according to a third embodiment of the present invention.

### DESCRIPTION OF THE EMBODIMENTS

As described in the technical background of the present invention, the image data captured from a document by an image reading device, such as a charge coupled device (CCD) are sent to an image- processing unit including an analog-to-digital converter (ADC), a control circuit, a memory device and an output interface. Initially, the analog-to-digital converter digitizes the image data from the image reading device and outputs the digitized image data to the control circuit, for example, an application specific integrated circuit (ASIC). The memory device is used to serve as a temporary storage device for storing the information from the control circuit, such as the digitized image data.

The memory device used in the conventional image processing system, like a scanner, mainly includes a memory cell array having a plurality of memory cells arranged in rows and columns. Generally, all the memory cells of the memory device used in the image processing system are functional memory cells. A memory device having defective memory cells is not used as an image information storage device, thus the functional memory cells in the defective memory device are wasted. Accordingly, the present invention develops a method for efficiently and economically utilizing the defective memory device in the image processing system.

The present method for improving utilization of a defective memory device in an image processing system can be practiced according to the following embodiments.

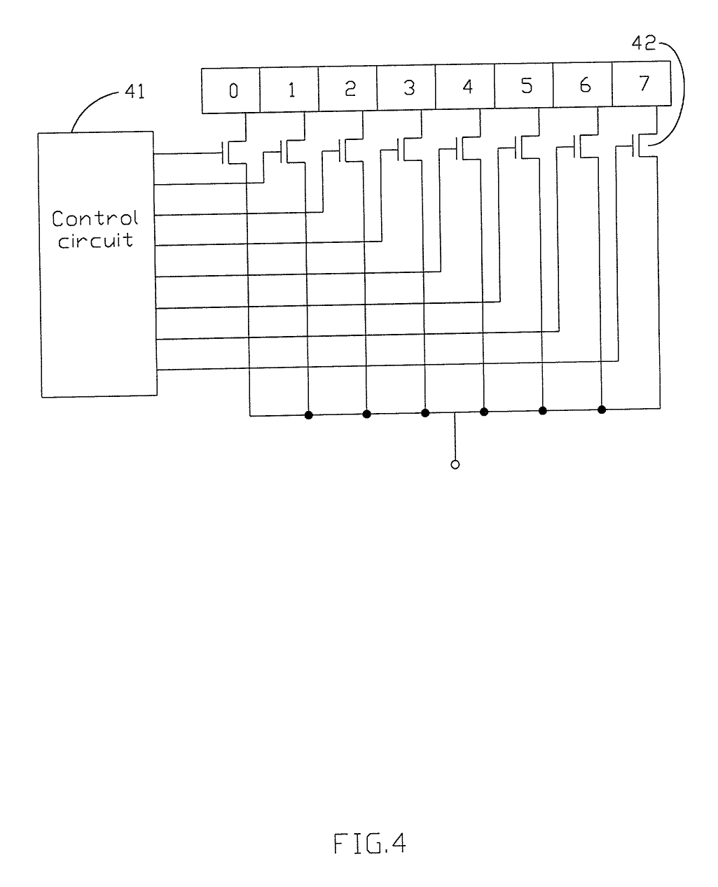

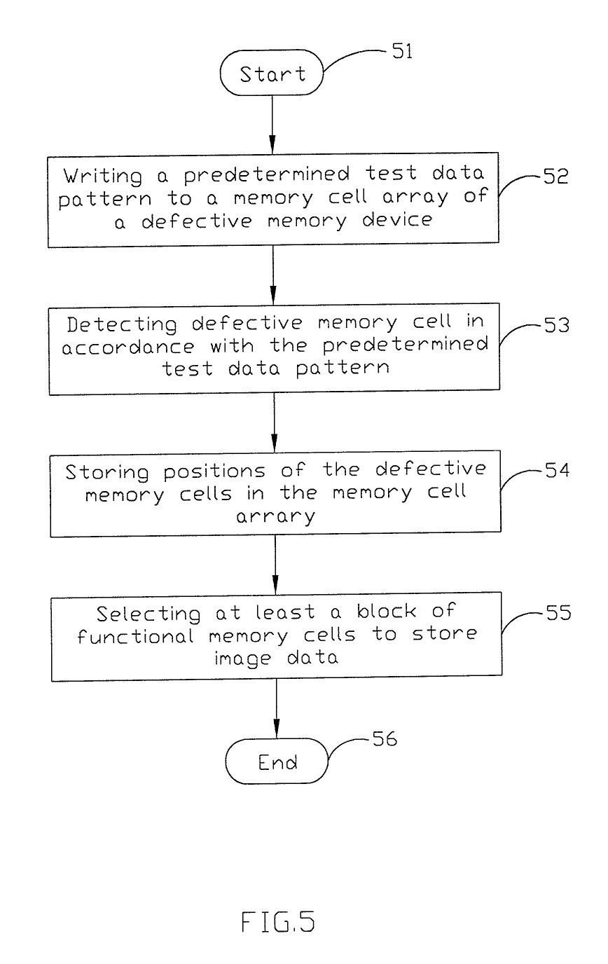

FIG. 5 is a flow chart of a first embodiment of the present invention. When power is initially applied to the image processing system, the detection of defective memory cells is executed. As step 52, a predetermined test data pattern is written to the memory cell array of the defective memory device use in the image processing system. Referring to FIG. 4, the detection of the defective memory cells can be executed by the control circuit 41. The predetermined test data pattern can be written to the memory cells 42 from the control circuit 41. For example, a (55, AA) pattern can be written to the memory cells 42 when the defective memory device comprises an 8-bit memory cell array, each memory cell having one bit, as shown in FIG. 4, wherein 55=0×0101, 0×0101, AA=0×1010, 0×1010. When 55 is written to the memory cell array of the defective memory device, meaning bit 0, bit 2, bit 4 and bit 6 are to be detected. When AA is written to the memory cell array of the defective memory device, meaning bit 1, bit 3, bit 5 and bit 7 are to be detected. As step 53, the defective memory cells are detected in accordance with the predetermined test data pattern.

Following, in step 54, storing positions of the defective memory cells in the memory cell array. Then, as step 55, selecting at least a block of functional memory cells to store image data obtained from the image reading device when an image capture operation is performed. According to the first embodiment, the defective memory device can perform normally and is not influenced by the defective memory cells therein.

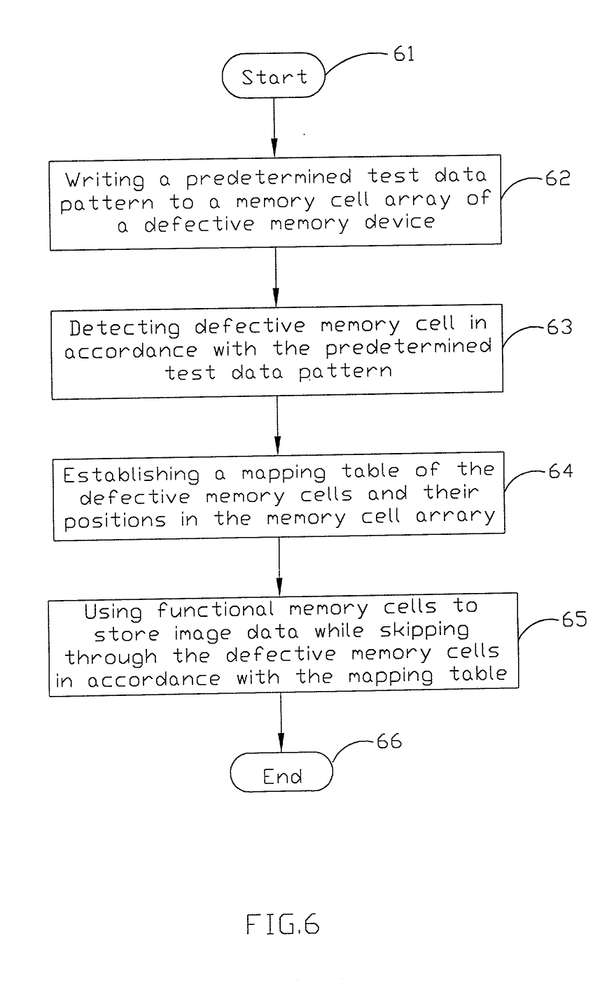

FIG. 6 is a flow chart of a second embodiment of the present invention. Steps 61 to 63 are the same with steps 51 to 53 of the first embodiment. While in the second embodiment, a mapping table of the defective memory cells and their positions in the memory cell array is established in step 64. Then, as step 65, when an image capture operation is performed, the functional memory cells of the defective memory device are used to store image data obtained from the image reading device while the defective memory cells are skipped over in accordance with the mapping table.

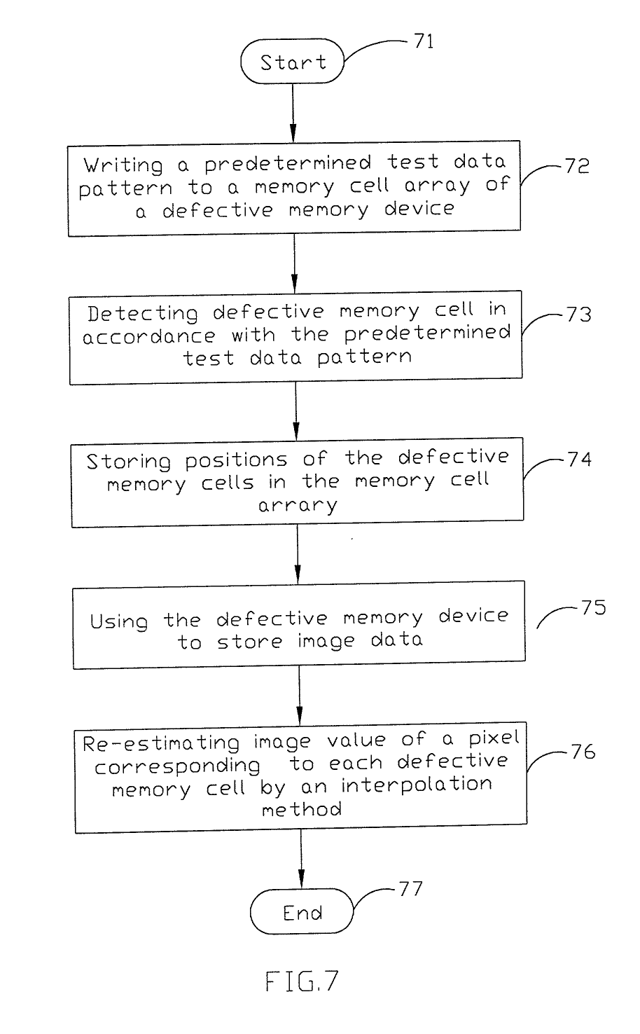

FIG. 7 is a flow chart of a third embodiment of the present invention. Steps 71 to 74 are the same with steps 51 to 54 of the first embodiment. In the third embodiment, as step 75, when an image capture operation is performed, the whole memory cell array of the defective memory device is used to store the image data obtained from the image reading device. Then, as step 76, the image value of a pixel corresponding to one of the defective memory cells is re-estimated by an interpolation method in accordance with image values of pixels adjacent to the pixel corresponding to the defective memory cell.

According to the present invention, one or more defective memories, arising during the semiconductor memory manufacturing process, can be utilized alone or together in an image processing system to serve as an image data storage device. The production cost of the image processing system is significantly reduced. The storage capacity of the memory device used in the image processing system is also increased.

The embodiments are only used to illustrate the present invention, not intended to limit the scope thereof. Many modifications of the embodiments can be made without departing from the spirit of the present invention.

What is claimed is:

1. A method for improving utilization of a defective memory device in an image processing system, comprising:
writing a predetermined test data pattern to a memory cell array of a memory device used in said image processing system;
detecting defective memory cells in accordance with said predetermined test data pattern;
storing positions of said defective memory cells in said memory cell array; and
selecting at least a block of said memory cell array consisting of functional memory cells, serving for storing image data obtained by an image reading device of said image processing system.

2. The method of claim 1, wherein said predetermined test data pattern is established by a (55, AA) pattern when said memory device comprises an 8-bit memory cell array.

3. A method for improving utilization of a defective memory device in an image processing system, comprising:
writing a predetermined test data pattern to a memory cell array of a memory device used in said image processing system;
detecting defective memory cells in accordance with said predetermined test data pattern;
establishing a mapping table of said defective memory cells and their positions in said memory cell array; and
using functional memory cells in said memory cell array for storing image data obtained by an image reading device of said image processing system, while skipping through said defective memory cells in accordance with said mapping table.

4. The method of claim 3, wherein said predetermined test data pattern is established by a (55, AA) pattern when said memory device comprises an 8-bit memory cell array.

5. A method for improving utilization of a defective memory device in an image processing system, comprising:
writing a predetermined test data pattern to a memory cell array of a memory device used in said image processing system;
detecting defective memory cells in accordance with said predetermined test data pattern;
storing positions of said defective memory cells in said memory cell array;
using said memory device for storing image data obtained by an image reading device of said image processing system; and
re-estimating an image value of a pixel corresponding to each said defective memory cell by an interpolation method.

6. The method of claim 5, wherein said predetermined test data pattern is established by a (55, AA) pattern when said memory device comprises an 8-bit memory cell array.
